(19) United States
(12) Patent Application Publication
(10) Pub. No.: US 2013/0146132 A1
(43) Pub. Date: Jun. 13, 2013

(54) CRYSTALLINE SILICON-BASED SOLAR CELL

(71) Applicants: Takashi Kuchiyama, Settsu-shi (JP); Kenji Yamamoto, Settsu-shi (JP); Masashi Yoshimi, Settsu-shi (JP)

(72) Inventors: Takashi Kuchiyama, Settsu-shi (JP); Kenji Yamamoto, Settsu-shi (JP); Masashi Yoshimi, Settsu-shi (JP)

(73) Assignee: KANEKA CORPORATION, Osaka-shi, Osaka (JP)

(21) Appl. No.: 13/816,216

(22) PCT Filed: Aug. 3, 2011
(86) PCT No.: PCT/JP2011/067783

§ 371 Date: Feb. 8, 2013

(30) Foreign Application Priority Data
Aug. 9, 2010 (JP) 2010-178886

(51) Int. Cl. H01L 31/0224

(52) U.S. Cl. CPC H01L 31/022466
USPC 136/255

(57) ABSTRACT

The present invention improves a photoelectric conversion efficiency of a crystalline silicon-based solar cell. The crystalline silicon based solar cell includes a silicon-based thin-film of a first conductivity type and a first transparent electrode layer, in this order, on one surface of a conductive single-crystal silicon substrate, and a silicon-based thin-film of the opposite conductivity type and a second transparent electrode layer, in this order, on the other surface of the conductive single-crystal silicon substrate. The first and second transparent electrode layers are each formed of a transparent conductive metal oxide, and the first transparent electrode layer preferably has at least two layers, and a total thickness of 50 to 120 nm, wherein the carrier density of the substrate-side electroconductive layer is higher than that of the surface-side electroconductive layer, and the carrier density of the surface-side electroconductive layer is 1 to 4×10²⁰ cm⁻³.

### TECHNICAL FIELD

The invention relates to a crystalline silicon-based solar cell having a heterojunction on a surface of a single-crystal silicon substrate.

### BACKGROUND ART

Crystalline silicon-based solar cells using crystalline silicon substrates are high in photoelectric conversion efficiency, and thus have already been widely and generally used in solar power generation systems. Among solar cells, a particular crystalline silicon-based solar cell in which an amorphous silicon-based thin-film having a band gap different from that of a single-crystal silicon is formed on a surface of the crystalline silicon substrate to produce a diffusion potential is called a heterojunction solar cell.

Among heterojunction-type solar cells, a solar cell having an intrinsic amorphous silicon thin-film between a conductive amorphous silicon-based thin-film for forming a diffusion potential and a single-crystal silicon substrate is known as one embodiment of a crystalline silicon-based solar cell with a high conversion efficiency. By forming an intrinsic amorphous silicon thin-film between a single-crystal silicon substrate and a conductive amorphous silicon-based thin-film, defects present on the surface of single-crystal silicon (principally dangling bonds of silicon) can be terminated with hydrogen while reducing generation of new defect levels. In addition, by forming an intrinsic amorphous silicon thin-film, carrier-introduction impurity can be prevented from diffusing to the surface of single-crystal silicon at the time of forming a conductive amorphous silicon-based thin-film.

In this heterojunction solar cell, a transparent electrode layer is further formed on the surface of the conductive amorphous silicon-based thin-film. The transparent electrode preferably has high optical transparency and low resistance, and for the material thereof, a transparent conductive metal oxide such as crystalline indium tin complex oxide (ITO). Patent Document 1 describes a method of improving the alkali resistance of a transparent electrode layer by controlling the crystallinity and orientation angle of ITO. Patent Document 2 reports that a transparent electrode layer using, as a material, indium oxide doped with tungsten has a resistivity of 3 to 9×10⁻⁴ Ω·cm at a thickness of 100 nm.

As described above, the characteristics of the solar cell can be controlled by the type of material used for transparent electrode layer. However, indium oxide doped with tungsten as in Patent Document 2 may cause an increase in costs, for example, due to a necessity of adding zinc in a slight amount as a coagulant in a step for producing a target used for deposition. In the heterojunction-type solar cell, the transparent electrode layer is important in extraction of photoinduced carriers, but improvement of carrier extraction efficiency cannot be expected merely by making the transparent electrode layer less resistant. For improving carrier extraction efficiency, it is necessary to improve the condition of the electrical junction between the transparent electrode layer and the conductive amorphous silicon-based thin-film, but in Patent Document 2, the doped amount of tungsten is only about 1%, and therefore improvement of the electrical junction cannot be expected despite the transparency of the transparent electrode layer being excellent.

### PRIOR ART DOCUMENTS

### Patent Documents

Patent Document 1: JP 4162447 B1
Patent Document 2: JP 2007-250927 A

### SUMMARY OF THE INVENTION

### Problems to be Solved by the Invention

In view of the above, an object of the present invention is to obtain a crystalline silicon-based solar cell having a high photoelectric conversion characteristic by improving an electrical junction between a silicon-based thin-film and a transparent electrode layer.

### Means for Solving the Problems

As a result of conducting vigorous studies in view of the above-mentioned problems, the inventors have found that in a crystalline silicon-based solar cell using a conductive single-crystal silicon substrate, photoelectric conversion efficiency, especially an output electric current, can be improved by using a specific transparent electrode layer.

The present invention relates to a crystalline silicon-based solar cell including a silicon-based thin-film of a first conductivity type and a first transparent electrode layer, in this order, on one surface of a conductive single-crystal silicon substrate of the first conductivity type or an opposite conductivity type; and a silicon-based thin-film of the opposite conductivity type and a second transparent electrode layer, in this order, on the other surface of the conductive single-crystal silicon substrate. The first transparent electrode layer and the second transparent electrode layer are each formed of a transparent conductive metal oxide. The first transparent electrode layer preferably satisfies the following requirements (i) to (iii).

(i) at least two layers, including a substrate-side electroconductive layer and a surface-side electroconductive layer, are provided in the first transparent electrode layer;

(ii) the total thickness of the first transparent electrode layer is 50 to 120 nm; and

(iii) the carrier density of the substrate-side electroconductive layer is higher than the carrier density of the surface-side electroconductive layer, and the carrier density of the surface-side electroconductive layer is 1 to 4×10²⁰ cm⁻³.

In one embodiment, the crystalline silicon-based solar cell of the present invention includes a first intrinsic silicon-based thin-film between the conductive single-crystal silicon substrate of the first conductivity type or an opposite conductivity type, and the silicon-based thin-film of the first conductivity type; and a second intrinsic silicon-based thin-film between the conductive single-crystal silicon substrate and silicon-based thin-film of the opposite conductivity type.

The thickness of the substrate-side electroconductive layer is preferably in the range of 5 nm to 40 nm. Further, it is preferable that the thickness d_{A} of the substrate-side electroconductive layer and the thickness d_{B} of the surface-side electroconductive layer satisfy 0.5≦d_{B}/(d_{A}+d_{B})≦0.95.

In the crystalline silicon-based solar cell of the present invention, the substrate-side electroconductive layer and the surface-side electroconductive layer are preferably not fully-crystallized, and are especially preferably amorphous.

In one embodiment, a thickness of the conductive single-crystal silicon substrate is 250 μm or less. In one embodiment, collecting electrode(s) on each of the first transparent electrode layer and the second transparent electrode layer are further provided.

### Effects of the Invention

In a crystalline silicon-based solar cell of the present invention, a first transparent electrode layer is composed of two or more layers, and a substrate-side electroconductive layer in contact with a crystalline silicon-based thin-film has a relatively high carrier density. Thus, an electrical junction between the silicon-based thin-film and the transparent electrode layer is improved, so that a photoinduced conductive carrier can be efficiently extracted to an electrode. Since a surface-side electroconductive layer of the first transparent electrode layer has a relatively low carrier density, absorption of light by the transparent electrode layer is suppressed, so that a crystalline silicon-based solar cell excellent in photoelectric conversion efficiency may be obtained.

### BRIEF DESCRIPTION OF THE DRAWINGS

FIG. 1 is a schematic sectional view of a crystalline silicon-based solar cell according to one embodiment of the present invention.

### DESCRIPTION OF EMBODIMENTS

The present invention relates to a crystalline silicon-based solar cell using a conductive single-crystal silicon substrate (hereinafter, also referred to as a “substrate”), and is characterized by having a specific transparent electrode layer on the substrate. The crystalline silicon-based solar cell of the present invention includes a silicon-based thin-film of a first conductivity type and a first transparent electrode layer on one surface of a conductive single-crystal silicon substrate 1 of the first conductivity type or an opposite conductivity type, and a silicon-based thin-film of the opposite conductivity type and a second transparent electrode layer on the other surface of the conductive single-crystal silicon substrate. That is, the crystalline silicon-based solar cell of the present invention includes a first transparent electrode layer, a silicon-based thin-film of a first conductivity type, a conductive single-crystal silicon substrate of the first conductivity type or an opposite conductivity type, a silicon-based thin-film of the opposite conductivity type and a second transparent electrode layer in this order.

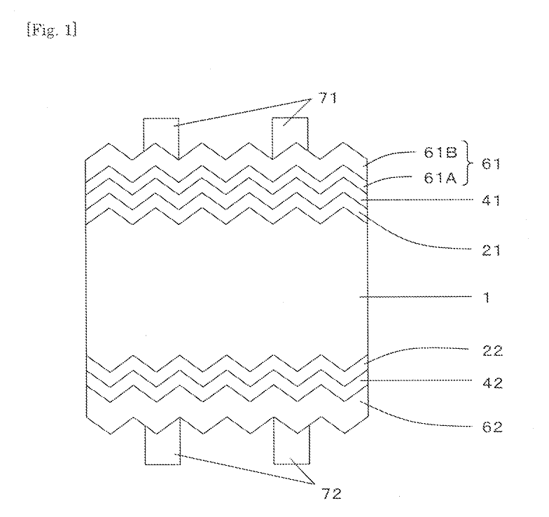

FIG. 1 is a schematic sectional view of a crystalline silicon-based solar cell according to one embodiment of the present invention. It is preferable that the crystalline silicon-based solar cell include a first intrinsic silicon-based thin-film 21 and a second intrinsic silicon-based thin-film 22 between a conductive single-crystal silicon substrate 1 and a silicon-based thin-film 41 of a first conductivity type and between the conductive single-crystal silicon substrate 1 and a silicon-based thin-film 42 of the opposite conductivity type, respectively. Generally, collecting electrodes 71, 72 are formed on transparent electrode layers 61, 62. It is preferable that a protective layer (not shown) be further formed on the collecting electrode.

In this crystalline silicon-based solar cell, the condition of an electrical junction between a conductive amorphous silicon-based thin-film (thin-film 41 of a first conductivity type or silicon-based thin-film 42 of an opposite conductivity type) and a transparent electrode layer is very important in terms of photoinduced carrier extraction efficiency. For example, when a junction interface between a p-type silicon-based thin-film and a transparent electrode layer is formed, a thermal equilibrium state is formed so that the fermi level of the p-type silicon-based thin-film and the fermi level of the transparent electrode layer are equalized. Generally, the p-type silicon-based thin-film has a carrier density lower than that of the transparent electrode layer, and therefore when a thermal equilibrium state is formed at the junction interface, a band on the p-type silicon-based thin-film side may bend easily.

The band bending direction at the junction interface formation depends on the height of the fermi level of each layer. For example, when the fermi level of the p-type silicon-based thin-film is lower than the fermi level of the transparent electrode layer (the work function of the p-type silicon-based thin-film is larger than the work function of the transparent electrode layer), the band of the p-type silicon-based thin-film bends upward, and a thermal equilibrium state is formed at the junction interface. Here, “upper and lower”, and “high and low” are relative to a vacuum level corresponding to an upper and high state.

The fermi level is known to have a correlation with the carrier density, and when the carrier is an electron, the fermi level and the carrier density are represented by the following relational expression.

$${n}_{c} = {n}_{0} {e}^{\frac{{E}_{c} - {E}_{F}}{kT}} \qquad [ Formula 2 ]$$

Here, n_{c} represents a carrier density, n₀ represents a doping concentration, k represents a Boltzmann constant, T represents a temperature, E_{c} represents a bottom level of a conduction band, and E_{F} represents a fermi level. It is apparent therefrom that the difference between the bottom level of the conduction band and the fermi level becomes larger, i.e. the fermi level becomes lower, as the carrier density increases.

In the present invention, the state of an electrical junction between the transparent electrode layer and the conductive silicon-based thin-film is improved by employing a specified transparent electrode layer. Thus, recombination of carriers, which occurs due to band bending of the conductive silicon-based thin-film, is suppressed, so that the photoelectric conversion efficiency of the crystalline silicon-based solar cell can be improved. The components of the crystalline silicon-based solar cell of the present invention will be described below.

First, the conductive single-crystal silicon substrate of the first conductivity type or an opposite conductivity type will be described. Generally, the single-crystal silicon substrate contains an impurity that supplies charges to silicon, and has conductivity. The conductive single-crystal silicon substrates containing an impurity include an n-type single-crystal silicon substrate containing impurity that introduces electrons to Si atoms (e.g. phosphorus atoms), and a p-type single-crystal silicon substrate containing an impurity that introduces holes to Si atoms (e.g. boron atoms). In this specification, “a first conductivity type and an opposite conductivity type” refer to an n-type and a p-type or a p-type and an n-type.

The single-crystal silicon substrate is preferably cut out such that the light-incidence plane is the (100) plane. This is because when the single-crystal silicon substrate is etched, a textured surface structure is easily formed by anisotropic etching that exploits the difference in etching rate between the (100) plane and the (111) plane. Generally, the texture dimension increases as etching proceeds. For example, the texture dimension increases if the etching time is prolonged. The texture dimension can also be increased by increasing the etchant concentration or supply rate, elevating the liquid temperature, or the like so that the reaction rate is increased. The etching rate also varies depending on the surface state when etching is started, and therefore a surface subjected to a step such as rubbing and a surface not subjected to such a step generally have different texture dimensions. Defects are easily generated at sharp troughs formed on the substrate surface due to compressive stress when a thin-film is formed. Thus, it is preferable that isotropic etching that has low selectivity between the (100) plane and the (111) plane be carried out, as a step for moderating the shape of troughs and crests of the textured surface structure, after etching is carried out for forming the texture.

In one embodiment, the thickness of the conductive single-crystal silicon substrate is preferably 250 μm or less. Reduction of the thickness of the silicon substrate has an advantage that the amount of silicon used decreases, so that cost reduction can be achieved, and the silicon substrate is easily obtained. On the other hand, if the thickness of the silicon substrate is excessively small, the short circuit current density may be reduced because natural light (sunlight) is not sufficiently absorbed by the silicon substrate, and mechanical strength may be reduced. Thus, the thickness of the conductive single-crystal silicon substrate 1 is preferably 50 μm or more, more preferably 70 μm or more. When unevenness is formed on the surface of the silicon substrate, the thickness of the silicon substrate is represented by a distance between lines that link raised portions of unevenness structures on the light incident side and on the back surface side.

The crystalline silicon-based solar cell of the present invention includes a p-type silicon-based thin-film and a transparent electrode layer, in this order, on one surface of a conductive single-crystal silicon substrate, and an n-type silicon-based thin-film and a transparent electrode layer, in this order, on the other surface of the conductive single-crystal silicon substrate. Intrinsic silicon-based thin-films are preferably provided between the single-crystal silicon substrate and the p-type silicon-based thin-film and between the conductive single-crystal silicon substrate and the n-type silicon-based thin-film, respectively, from the viewpoint of effectively performing passivation of the single-crystal silicon surface while suppressing diffusion of an impurity to the single-crystal silicon substrate. In this specification, the term “intrinsic” layer is not limited to a completely intrinsic layer containing no conductive impurity, but also encompasses a substantially intrinsic layer of “weak n-type” or “weak p-type” which contains a slight amount of an n-type impurity or p-type impurity to the extent that the silicon-based thin-film can function as an intrinsic layer (i-type layer).

When the conductive single-crystal silicon substrate is used as material for a solar cell, a strong electric field is provided by setting the heterojunction on the incident side, where light incident to the single-crystal silicon substrate is most absorbed, to a reverse junction, so that electron/hole pairs are effectively separated and collected. Therefore, in the heterojunction solar cell, the heterojunction on the light incident side of the single-crystal silicon substrate is preferably a reverse junction. When comparing the hole and the electron, the electron, which has a lower effective mass and scattering cross-sectional area, generally has a high mobility, and therefore the p-type layer is preferably provided on the light incident side. Accordingly, in the present invention, the single-crystal silicon substrate is preferably an n-type single-crystal silicon substrate.

When this n-type single-crystal silicon substrate is used, one example of the preferred structure of the present invention is a structure including a protective layer, a collecting electrode, a transparent electrode layer, a p-type amorphous silicon-based thin-film, an i-type amorphous silicon-based thin-film, an n-type single-crystal silicon substrate, an i-type amorphous silicon-based thin-film, an n-type amorphous silicon-based thin-film, a transparent electrode layer, a collecting electrode and a protective layer, in this order. In such a configuration, the n-type amorphous silicon-based thin-film (also referred to as an n layer) side is preferably the back surface side.

When the n layer is provided on the back surface side as described above, a reflection layer (not shown) is preferably formed on the transparent electrode layer on the back surface side, from the viewpoint of light confinement. The reflection layer means a layer that adds to the solar cell a function of reflecting light. For example, the reflection layer may be a metal layer of Ag, Al or the like, or may be a layer formed by using a white high-reflective material made of fine particles of a metal oxide such as MgO, Al₂O₃ or white zinc. A layer that has a photonic structure having a reflectivity to light having a wavelength in a specific range may be used as a reflection layer by utilizing interference of reflected light at the interface within a multilayer film. This photonic structure is formed by a multilayer film constituted by stacking two or more dielectric layers different in refractive index and thickness.

An antireflective layer (not shown) is preferably formed on the transparent electrode layer on the light incident side. As the antireflective layer, a layer having the aforementioned photonic structure, or the like is suitably used. A ceramic-based material and a dielectric layer are insulators, and therefore when such a material is used as a reflection layer or an antireflective layer, it is preferable that the reflection layer be formed on the collecting electrode after the collecting electrode be formed on the transparent electrode layer.

When the p-type single-crystal silicon substrate is used as the conductive single-crystal silicon substrate, one example of the preferred structure of the present invention is a protective layer/collecting electrode/transparent electrode layer/n-type amorphous silicon-based thin-film/i-type amorphous silicon-based thin-film/p-type single-crystal silicon substrate/i-type amorphous silicon-based thin-film/p-type amorphous silicon-based thin-film/transparent electrode layer/collecting electrode/protective layer (not shown), or the like. In this case, the n layer side is preferably the incident surface side, with the reverse junction part on the light incident side, from the viewpoint of increasing carrier collection efficiency.

On the single-crystal silicon substrate, intrinsic silicon-based thin-films are formed on both the front and back surfaces as necessary, and a p-type silicon-based thin-film and an n-type silicon-based thin-film are formed thereon. The method for forming these silicon-based thin-films on the single-crystal silicon substrate is preferably a plasma enhanced CVD method. Conditions used for forming the silicon-based thin-films are preferably as follows: a substrate temperature of 100 to 300° C.; a pressure of 20 to 2600 Pa; and a high-frequency power density of 0.003 to 0.5 W/cm². A source gas used to form the silicon-based thin-films may be a silicon-containing gas such as SiH₄ or Si₂H₆, or a mixed gas of silicon-based gas and H₂. A dopant gas for forming the p-type layer or the n-type layer is preferably, for example, B₂H₆ or PH₃. The amount of impurity such as P or B added, in this case, is sufficient to be a trace amount; thus, it is preferred to use a mixed gas wherein B₂H₆ or PH₃ is beforehand diluted with SiH₄ or H₂. When a gas containing different element, such as CH₄, CO₂, NH₃ or GeH₄, is added thereto, silicon is alloyed so that the energy gaps of the conductive silicon-based thin-films can be changed.

The intrinsic silicon-based thin-films are preferably i-type amorphous silicon-based thin-films. Among them, i-type hydrogenated amorphous silicon composed of silicon and hydrogen is more preferable. When i-type hydrogenated amorphous silicon is formed on a single-crystal silicon substrate by a CVD method, surface passivation can be effectively performed while suppressing diffusion of impurities to the single-crystal silicon substrate. When the amount of hydrogen in the film is changed in the thickness direction, the layer may have an energy gap profile effective for collecting carriers. The thickness of the intrinsic silicon-based thin-film is preferably in the range of 2 nm to 8 nm. If the thickness of the intrinsic silicon-based thin-film is too small, it may be hard to perform a function as a passivation layer. If the thickness of the intrinsic silicon-based thin-film is too large, the conversion characteristic may be reduced due to an increase in resistance.

The p-type silicon-based thin-film is preferably a p-type hydrogenated amorphous silicon layer or a p-type amorphous silicon oxide layer. The p-type hydrogenated amorphous silicon layer is preferable for suppression of impurity diffusion and reduction of series resistance. On the other hand, to reduce optical loss by a wide-gap low-refractive index layer, the p-type amorphous silicon oxide layers are also preferably used.

The n-type silicon-based thin-film is preferably, for example, an n-type hydrogenated amorphous silicon layer, an n-type amorphous silicon nitride layer or an n-type microcrystalline silicon layer. Among the n-type silicon-based thin-films described above, an n-type silicon layer, to which impurity other than dopant is not intentionally added, is preferable, from the viewpoint of suppressing generation of defects.

On the other hand, by adding oxygen and carbon to silicon, an optical advantage may be obtained because an effective optical gap can be widened, and the refractive index decreases. Accordingly, oxygen and carbon may be added to at least one of the above-mentioned silicon-based layers within the bounds of CO₂/SiH₄<10 and CH₄/SiH₄<3.

The thickness of the above-mentioned conductive (p-type and n-type) silicon-based thin-film is preferably in a range of 3 nm to 12 nm. The conductive silicon-based thin-film is a layer required for extracting carriers to a transparent electrode, and if the thickness thereof is too small, carrier movement may be rate-limited. On the other hand, if the thickness of the conductive silicon-based thin-film is too large, light absorption may be reduced.

In the present invention, the first transparent electrode layer and the second transparent electrode layer are formed, respectively, on the conductive silicon-based thin-film. The thickness of each of the first and second transparent electrode layers is preferably 50 nm or more and 120 nm or less, further preferably 70 to 100 nm, from the viewpoint of transparency and conductivity. It suffices that the transparent electrode layer has a conductivity required for transport of carriers to the collecting electrode. On the other hand, if the transparent electrode layer is too thick, the transmittance decreases due to absorption losses in the layer itself, and as a result, photoelectric conversion efficiency may be reduced.

For the first and second transparent electrode layers, generally, a thin-film made of a transparent conductive metal oxide, for example, indium oxide, tin oxide, zinc oxide, titanium oxide or a complex oxide thereof is used. Above all, an indium-based complex oxide having indium oxide as a main component is preferable. Indium tin oxide (ITO) is especially suitably used from the viewpoint of the high conductivity and transparency.

In the present invention, the first transparent electrode layer has two layers: a substrate-side electroconductive layer and a surface-side electroconductive layer. In FIG. 1, a configuration is shown in which the first transparent electrode layer 61 on the silicon-based thin-film 41 of a first conductivity type is composed of two layers: a substrate-side electroconductive layer 61A and a surface-side electroconductive layer 61B. By configuring the transparent electrode layer to be composed of two or three or more layers having different carrier densities, the transparency and conductivity of the transparent electrode layer are secured while improving electrical junction at the interface between the transparent electrode layer and the adjacent conductive silicon-based thin-film, so that the light capture efficiency of the solar cell can be improved.

When the transparent electrode layer is composed of two or more layers, the carrier density of the electroconductive layer on the substrate side is preferably higher than the carrier density of the electroconductive layer on the surface side. Thus, by increasing the carrier density of the substrate-side electroconductive layer adjacent to the conductive silicon-based thin-film, the contact between the conductive silicon-based thin-film and the transparent electrode layer is improved. Particularly, by configuring the first transparent layer adjacent to the p-type silicon-based thin-film to be composed of two or more layers as described above, and using as the substrate-side electroconductive layer an electroconductive layer having a high carrier density, recombination resulting from flow of carriers in a reverse direction due to band bending of the p layer is suppressed. As a result, photoelectric conversion efficiency can be improved. That is, in the crystalline silicon-based solar cell of the present invention, preferably the silicon-based thin-film 41 of a first conductivity type is of a p-type, the silicon-based thin-film 42 of the opposite conductivity type is of an n-type, and the first transparent electrode layer 61 on the p-type silicon-based thin-film 41 is configured to be composed of two layers as described above

The first transparent electrode layer 61 may be composed of two layers, or may be composed of three or more layers. For example, when the transparent electrode layer is composed of three layers, a transparent electrode layer may have one more transparent electroconductive layer between the substrate-side electroconductive layer 61A and the surface-side electroconductive layer 61B, and as a further example, a transparent electrode layer may include a transparent electroconductive layer having a thickness of several nm is formed on the surface side (collecting electrode 71 forming surface side) as compared to the surface-side electroconductive layer 61B, for increasing adhesiveness with the collecting electrode, and so on. For ease of deposition, mass productivity and so on, the transparent electrode layer is preferably composed of two layers.

The carrier density of the surface-side electroconductive layer is preferably 4×10²⁰ cm⁻³ or less. When the surface-side electroconductive layer is made to have a low carrier density, photoelectric conversion efficiency, particularly the short circuit current density, can be improved because the transparent electrode layer has high permeability over a wide wavelength range. The lower limit of the carrier density of the surface-side electroconductive layer is not particularly limited. The carrier density of the surface-side electroconductive layer is preferably 5×10¹⁹ cm⁻³ or more for obtaining a low-resistant transparent electrode layer. The carrier density of the surface-side electroconductive layer is preferably 7×10¹⁹ cm⁻³ or more, more preferably 1×10²⁰ cm⁻³ or more, for formability of the transparent conductive film.

The transparent electroconductive layer having a low carrier density is preferable for transparency (light capture efficiency to the solar cell) but, on the other hand, conductivity may be reduced. Therefore, in a transparent electrode layer composed only of a transparent electroconductive layer having a low carrier density, it may be difficult to form a good electrical junction between the transparent electrode layer and the conductive silicon-based thin-film. In the present invention, a substrate-side electroconductive layer having a relatively high carrier density is provided between the surface-side transparent electroconductive layer having a low carrier density and the silicon-based thin-film, so that both electrical junction with the conductive layer and optical transparency can be achieved.

The carrier density of the substrate-side electroconductive layer 61A is preferably about 5×10²⁰ cm⁻³ to 1×10²¹ cm⁻³, more preferably about 6×10²⁰ cm⁻³ to 9×10²⁰ cm⁻³. By ensuring that the carrier density of the silicon substrate-type electroconductive layer falls within the aforementioned range, the conductivity of the transparent electrode layer and electrical junction with the silicon-based thin-film can be improved. When the carrier density of the silicon substrate-type electroconductive layer falls within the aforementioned range, band bending of the silicon-based thin-film is inhibited from excessively increasing, so that a depletion region generated in the silicon-based thin-film can be made to fall within a preferred range. As a result, photoinduced conductive carrier extraction efficiency can be improved.

Accordingly, the transparent electrode layer particularly on the light incident side is preferably configured to be composed of two or more layers including the substrate-side electroconductive layer and the surface-side electroconductive layer. In other words, in the crystalline silicon-based solar cell of the present invention, the first transparent electrode layer side is preferably at the light incident side. As described above, in the crystalline silicon-based solar cell of the present invention, it is preferable that the single-crystal silicon substrate is of an n-type and the light incident side is a p-type layer for electric current collection efficiency. In this case, the silicon-based thin-film 41 of a first conductivity type is a p-type silicon-based thin-film, and the silicon-based thin-film of the opposite conductivity type is an n-type silicon-based thin-film. That is, the preferred form of the present invention is a crystalline silicon-based solar cell including the first transparent electrode layer 61 having at least two layers: a substrate-side electroconductive layer and a surface-side electroconductive layer, the p-type silicon-based thin-film 41, the first intrinsic silicon-based thin-film 21, the n-type single-crystal silicon substrate 1, the second intrinsic silicon-based thin-film 22, the n-type silicon-based thin-film 42 and the second transparent electrode layer 62, in this order from the light incident side, referring to FIG. 1.

Also, when the transparent electrode layer on the back surface side is configured to be composed of two or more layers, reflected light can be made incident again to the conductive single-crystal silicon substrate efficiently while improving electrical junction between the transparent electrode layer and the conductive silicon-based thin-film to enhance electric current extraction efficiency. In particular, when the thickness of the conductive single-crystal substrate is small, i.e. 250 μm or less, it is important to make reflected light incident again, and therefore it is preferable that the transparent electrode layer on the back surface side be configured to have two or more layers. Thus, the first transparent electrode layer side may be the back surface side. Accordingly, it is also preferable that not only the first transparent electrode layer 61 but also the second transparent electrode layer 62 be configured to have two layers: a substrate-side electroconductive layer and a surface-side electroconductive layer, as described above.

The distribution of the carrier density of the transparent electrode is determined by fitting, using a Drude model, a dielectric function of an infrared region obtained by optical measurement such as, for example, spectroscopic ellipsometry. That is, by fitting by the Drude model, a thickness-direction profile of the relaxation time and resistivity distribution for the carrier can be obtained, and the carrier density can be calculated therefrom.

The thickness d_{A} of the substrate-side electroconductive layer in the first transparent electrode layer is preferably 5 nm or more, more preferably 8 nm or more, for improving the electrical junction at the interface between the transparent electrode layer and the conductive silicon-based thin-film and suppressing generation of pinholes. On the other hand, the substrate-side electroconductive layer is a layer having a relatively high carrier density, and therefore if its thickness is excessively large, a loss due to light absorption easily occurs. Therefore, the thickness d_{A} of the substrate-side electroconductive layer is preferably 40 nm or less, further preferably 30 nm or less.

The resistivity of the transparent electrode layer having a substrate-side electroconductive layer and a surface-side electroconductive layer is preferably 5.0×10⁻⁴ Ω·cm or less, more preferably 0.8×10⁻⁴ Ω·cm to 2.0×10⁻⁴ Ω·cm. The above-described conductivity originates generally from drift or diffusion of free electrons. According to the classical Drude's rule, a substance having free electrons may reflect or absorb light of a wavelength of 1000 nm or more. Therefore, if the resistivity is too low, the transmittance of the transparent electrode layer at long wavelengths may significantly decrease, leading to a reduction in conversion efficiency. On the other hand, if the resistivity of the transparent electrode layer is high, it is required to increase the number of collecting electrodes and increase the thickness of the transparent electrode layer, and therefore as a result, light capture efficiency may be reduced, so that improvement of performance cannot be expected.

For setting the resistivity of the first transparent electrode layer to fall within the above-described range, the thickness d_{B} of the surface-side electroconductive layer is preferably 25 nm to 114 nm, more preferably 50 nm to 90 nm. For forming a transparent electroconductive layer having a desired resistivity while improving an electrical junction at the interface between the transparent electrode layer and the conductive layer, it is preferable that the thickness d_{A} of the substrate-side electroconductive layer and the thickness d_{B} of the surface-side electroconductive layer satisfy 0.5≦d_{B}/(d_{A}+d_{B}) 0.95. The value of d_{B}/(d_{A}+d_{B}) is more preferably in a range of 0.5 to 0.95, further preferably in a range of 0.6 to 0.9. The thickness of the transparent electrode layer can be determined by cross-sectional observation using a scanning electron microscope (SEM) or a transmission electron microscopy (TEM).

When the second transparent electrode layer is composed of two or more layers like the first transparent electrode layer, it is preferable that the thickness of the substrate-side electroconductive layer and the thickness of the surface-side electroconductive layer in the second transparent electrode layer also be in the aforementioned ranges.

In the present invention, the substrate-side electroconductive layer and the surface-side electroconductive layer of the first transparent electrode layer each are preferably a transparent conductive metal oxide layer that is not fully-crystallized. “Not fully-crystallized” means that the degree of crystallinity is less than 100%, and an amorphous component is included. In the present invention, the substrate-side electroconductive layer and the surface-side electroconductive layer of the first transparent electrode layer are more preferably amorphous layers. “Amorphous layers” refers to those in which no crystal-specific peak is observed in X-ray diffraction. Examples of amorphous ITO films include those in which none of the diffraction peaks of (220), (222), (400) and (440) planes are observed by X-ray diffraction. Amorphous ITO films encompass those in which no X-ray crystal diffraction peak is observed because the crystal element size is small, even though crystal grains can be observed by high-resolution observation with a TEM or the like.

If the first transparent electrode layer is a layer that is not fully-crystallized, warpage of the solar cell is suppressed, so that high conversion efficiency can be maintained. In particular, when the thickness of the conductive single-crystal silicon substrate is small, i.e. 250 μm or less, warpage may occur after formation of the transparent electrode layer, leading to reduction of the conversion characteristic, but reduction of conversion efficiency by the warpage is suppressed as an amorphous transparent electrode layer is formed.

In the heterojunction solar cell, the intrinsic silicon-based thin-film and the conductive silicon-based thin-film are formed on the single-crystal silicon substrate almost symmetrically in terms of thickness on the front and the back, whereas the transparent electrode layer often varies in thickness between the light incident side and the back surface side. Thus, after transparent electrode layers are formed on both surfaces, stress given to the interface varies between the front-side and the back-side of the single-crystal silicon substrate, and warpage may easily occur due to mechanical strains in a heterojunction solar cell using a single-crystal silicon substrate having a small thickness. Formation of transparent electrode layers different in thickness on the light incident side and the back surface side is ascribable to the difference in design concept between the former and the latter. That is, for the transparent electrode layer on the light incident side, thickness is determined according to an optical design principally for transmitting sunlight incident into a cell efficiently (suppressing reflection), whereas for the transparent electrode layer on the back surface side, thickness is often determined according to an electrical design such as a resistance value principally for improving electricity extraction efficiency.

It is thought that if warpage occurs in the solar cell, a strain is generated at the interface between the conductive single-crystal silicon substrate and the silicon-based thin-film, so that an interface level is formed, leading to generation of defects (recombination center). If these defects are generated, the photoelectric conversion characteristic, especially an open circuit voltage, may be reduced. Steps for producing a solar cell after forming the transparent electrode layer, such as formation of a collecting electrode and measurement of conversion efficiency, are generally carried out with the solar cell fixed on a treatment table. At this time, a method is widely used in which air is exhausted from a hole bored in a treatment table to adsorb the solar cell to the treatment table (adsorption method). When this adsorption method is employed, an adsorption failure occurs and the solar cell is not fixed on the treatment table, so that production efficiency may be reduced, if the warpage amount of the cell is large. Further, if there is a warpage in the solar cell, an air gap may be created between the treatment table and the solar cell, and foreign matter that can damage the solar cell are drawn in from the air gap.

Generally, a crystalline conductive metal oxide has residual stress, and for example, a crystalline ITO film generally has residual compressive stress. In contrast, an amorphous conductive metal oxide has less or no residual stress as compared to a crystalline conductive metal oxide. Therefore, it is thought that by forming an amorphous film as the transparent electrode layer, a difference in stress between the front-side and the back-side of the single-crystal silicon substrate is reduced, so that warpage is suppressed.

It is preferable that not only the first transparent electrode layer but also the second transparent electrode layer be amorphous from the viewpoint of reducing warpage resulting from the difference in stress between the front-side and the back-side of the single-crystal silicon substrate.

The crystallinity of the transparent electrode layer can be evaluated by, for example, electron diffraction or X-ray diffraction in the cross-sectional direction. In addition, the crystallinity can also be evaluated by optical measurement such as a Raman spectrum of the cross section.

The first transparent electrode layer and the second transparent electrode layer can both be formed by a known method. Examples of the deposition method include a sputtering method, a metal organic chemical vapor deposition (MOCVD) method, a thermal CVD method, a plasma-enhanced CVD method, a molecular beam epitaxy (MBE) method and a pulse laser deposition (PLD) method.

The substrate temperature at the time of forming the transparent electrode layer is preferably 150° C. or lower. By setting the above-mentioned temperature, desorption of hydrogen from a silicon-based thin-film, and generation of a dangling bond associated with desorption of hydrogen can be suppressed. Thus, generation of a recombination center of carriers is suppressed to form a transparent electrode layer having high photoinduced carrier extraction efficiency. The amorphous transparent electrode layer can be formed at, for example, about 50° C. or less, e.g. room temperature, and therefore may contribute to improvement of productivity.

The carrier density and crystallinity of the transparent electrode layer can be appropriately adjusted by changing the material and composition of the conductive oxide, and deposition conditions (deposition method, substrate temperature, type and introduction amount of introduced gas, deposition pressure, power density, etc.). Taking formation of an ITO film as an example, a target having a tin oxide content of 3 to 12% by weight is preferably used when a stoichiometric oxide is used as a target. When a metal target is used, a target containing 1.5 to 6% by weight of tin, based on the total amount of indium and tin, is preferably used. The deposition is preferably performed under conditions including a substrate temperature of 20° C. to 200° C., a pressure of 0.1 Pa to 0.5 Pa and a power density of 0.2 mW/cm² to 1.2 mW/cm².

The conductive carriers in the transparent electrode originate from oxygen deficiency in which heterogeneous elements contained principally as a dopant are activated. Thus, if the introduction amount of an oxidative gas such as oxygen is decreased, and the substrate temperature is lowered, the carrier density may be increased. Also, by increasing the amount of heterogeneous elements (for example, tin in ITO), the carrier density may be increased. Since the level of carrier density varies depending on which of the dopant amount and the oxygen deficiency amount is a dominant factor for determining the carrier density, a production parameter effective for adjustment of the carrier density may vary depending on the type and amount of the dopant and various other deposition conditions.

If the power density during deposition is decreased, an amorphous film is easily obtained. In particular, in formation of the first transparent electrode layer, it is preferable to decrease the power density when the surface-side electroconductive layer is formed on the substrate-side electroconductive layer. By decreasing the power density during deposition, damage to a silicon thin-film and a single-crystal silicon substrate, which are ground layers, is reduced, so that a reduction in open circuit voltage and fill factor are suppressed. Also, by increasing the deposition pressure, an amorphous film may be easily obtained.

Collecting electrodes 71 and 71 are preferably formed on the first transparent electrode layer 61 and the second transparent electrode layer 62, respectively. The collecting electrodes can be formed by a known method such as an inkjet printing, screen printing, wire bonding or spraying method. It is preferable that the collecting electrodes be formed by screen printing for productivity. In screen printing, for example, a conductive paste made of metallic particles and resin binder is printed by screen printing.

After the collecting electrodes are formed, annealing of the cell may be performed, by which the conductive paste used for the collecting electrode is solidified in parallel. By annealing, improvement of interface characteristics such as improvement of the transmittance/resistivity ratio of the transparent electrode layer, and reduction of the contact resistance and interface level can be achieved. The annealing temperature is preferably kept at a high temperature range of around 100° C. above the temperature at which the silicon-based thin-film is formed. If the annealing temperature is too high, characteristics may be deteriorated due to diffusion of a dopant from the conductive silicon-based thin-film to the intrinsic silicon-based thin-film, formation of an impurity level resulting from diffusion of heterogeneous elements from the transparent electrode layer to the silicon region, formation of defects within amorphous silicon, and so on.

By coating the solar cell after formation of the collecting electrode with a film such as, for example, an ethylene vinyl acetate (EVA) resin to form a protective layer, its physical strength can be enhanced. The protective layer also has a role of preventing degradation of the silicon-based layer and the electrode layer by oxygen and moisture. Losses of optical characteristics can also be inhibited by subjecting the surface of a protective layer made of an EVA film or the like to a blasting treatment to impart a haze thereto. Another layer such as a reflection layer may be formed between the collecting electrode and the protective layer.

### EXAMPLES

Examples of the present invention will be specifically described below, but the present invention is not limited to the Examples below.

[Evaluation Method]

### (Thickness)

The thickness of a transparent electrode was determined by making an observation at a magnification of 100,000× using a SEM (Field Emission Type Scanning Electron Microscope 54800 manufactured by Hitachi High-Technologies Corporation).

(Carrier Density)

As a sample for Hall measurement, an ITO film was formed on alkali-free glass (trade name “OA-10” manufactured by Nippon Electric Glass Company, Limited) under deposition conditions identical to those for a substrate-side ITO layer 61 and a surface-side ITO layer 61B in each Example and Comparative Example. This sample was snapped into a 1 cm square, and metal indium was fused at the four corners thereof as an electrode. The Hall mobility was measured by the van der Pauw method based on a potential difference at the time of passing a current of 1 mA in the diagonal direction of a substrate at a magnetic force of 3500 gauss, and the carrier density was calculated.

(Crystallinity of Transparent Electrode)

The crystallinity of a transparent electrode layer was evaluated by identifying presence/absence of a peak, by an X-ray diffraction method, using a sample having an ITO film formed on alkali-free glass, which was identical to the above-mentioned sample for Hall measurement. The X-ray measurement was performed by a 2θ/θ method, and the measurement range of 2θ was set at 20 to 80°.

(Warpage)

After a first transparent electrode layer and a second electrode layer were formed, a cell before formation of a collecting electrode was left at rest on a horizontal table such that the first transparent electrode layer side (light incident side) was the upper surface.

(Photoelectric Conversion Characteristics)

Using a solar simulator, a crystalline silicon-based thin-film solar cell was irradiated with light of AM 1.5 in a light amount of 100 mW/cm² to measure the open circuit voltage (Voc), the short circuit current density (Jsc), the fill factor (F.F.) and conversion efficiency (Eff.).

### Example 1

A crystalline silicon-based solar cell schematically shown in FIG. 1 was prepared. The crystalline silicon-based solar cell of this Example is a heterojunction solar cell, wherein both surfaces of an n-type single-crystal silicon substrate 1 are textured surfaces. On the light incident side of the n-type single-crystal silicon substrate 1, a first intrinsic amorphous silicon layer 21, a p-type amorphous silicon layer 41, a first transparent electrode layer 61 and a collecting electrode 71 are formed in this order. The first transparent electrode layer has a two-layer structure in which a surface-side electroconductive layer 61B is formed on a substrate-side electroconductive layer 61A. On the back surface-side of the n-type single-crystal silicon substrate 1, a second intrinsic amorphous silicon layer 22, an n-type amorphous silicon layer 42, a second transparent electrode layer 62 and a collecting electrode 72 are formed in this order. This crystalline silicon-based solar cell was prepared in the following manner.

An n-type single-crystal silicon substrate having a light incident surface direction identical to (100) and having a thickness of 200 μm was washed in acetone, and thereafter immersed in an aqueous HF solution with a concentration of 2% by weight for 3 minutes to remove a silicon oxide covering on the surface. Thereafter, the substrate was rinsed twice with ultrapure water. The silicon substrate was immersed in 5/15 wt % aqueous KOH/isopropyl alcohol solution held at 70° C. for 15 minutes, and the surface of the substrate was etched to form a textured surface. Thereafter, the substrate was rinsed twice with ultrapure water. The surface of the single-crystal substrate 1 was observed using an atomic force microscope (AFM, manufactured by Pacific Nanotechnology, Inc.) to be mostly etched, and a pyramidal textured surface exposed at the (111) plane was formed.

The single-crystal silicon substrate 1 was introduced into a CVD device, and the intrinsic amorphous silicon layer 21 was formed in a thickness of 3 nm on the incident-side surface. The thickness of the silicon-based thin-film formed in this Example was calculated based on the assumption that the film was formed at the same deposition rate as a deposition rate determined from a value obtained by measuring, by spectroscopic ellipsometry (trade name: VASE, manufactured by J.A. Woollam Co. Inc.), the thickness of a film deposited on a glass substrate under the same conditions. Deposition conditions of the first intrinsic amorphous silicon layer 21 included a substrate temperature of 150° C., a pressure of 120 Pa, a SiH₄/H₂ flow ratio of 3/10 and an input power density of 0.011 W/cm².

On the first intrinsic amorphous silicon layer 21, a p-type amorphous silicon layer 41 was formed in a thickness of 4 nm. Deposition conditions of the p-type amorphous silicon layer 41 included: a substrate temperature of 150° C., a pressure of 60 Pa, a SiH₄/B₂H₆ flow ratio of 1/3, and a power density supply of 0.01 W/cm². B₂H₆ gas was used, wherein B₂H₆ concentration was diluted to 5000 ppm using H₂ gas.

Thereafter, on the back side of the single-crystal silicon substrate 1, a second intrinsic amorphous silicon layer 22 was formed with a thickness of 6 nm. Deposition conditions of the second intrinsic silicon layer 22 included a substrate temperature of 150° C., a pressure of 120 Pa, a SiH₄/H₂ flow ratio of 3/10, and an input power density of 0.011 W/cm². On the second intrinsic amorphous silicon layer 22, an n-type amorphous silicon layer 42 was formed with a thickness of 4 nm. Deposition conditions of the n-type amorphous silicon layer 42 included: a substrate temperature of 150° C., a pressure of 60 Pa, a SiH₄/PH₃ flow ratio of 1/2, and a power density supply of 0.01 W/cm². As the PH₃ gas, a diluting gas of which PH₃ concentration is diluted to 5000 ppm by H₂ was used.

On the p-type amorphous silicon layer 41, the substrate-side ITO layer 61A and the surface-side ITO layer 61B were sequentially formed as the first transparent electrode layer 61 by a sputtering method so that the total thickness of both the layers was 90 nm.

For formation of the substrate-side ITO layer 61A, ITO having a tin oxide content of 5% by weight was used as a target. As a carrier gas, argon was introduced at a flow rate of 50 sccm, and the layer was formed at a substrate temperature of 150° C., a pressure of 0.2 Pa and a power density of 0.5 W/cm² and in a thickness of 10 nm. For formation of the surface-side ITO layer 61B, ITO having a tin oxide content of 5% by weight was used as a target. As a carrier gas, an argon gas/oxygen gas was introduced at a flow rate of 50 sccm/1 sccm, and the layer was formed at a substrate temperature of 150° C., a pressure of 0.2 Pa and a power density of 0.5 W/cm² and in a thickness of 80 nm.

On the n-type amorphous silicon layer 42, an ITO film having a thickness of 100 nm was formed as the second transparent electrode layer 61 by a sputtering method. ITO having a tin oxide content of 5% by weight was used as a target. As a carrier gas, an argon gas and an oxygen gas were introduced at flow rates of 50 sccm and 1 sccm, respectively, and the layer was formed at a substrate temperature of 150° C. and a power density of 0.5 W/cm².

On each of the first transparent electrode layer 61 and the second transparent electrode layer 62, a silver paste was screen-printed as collecting electrodes 71 and 72, so that a comb-like pattern electrode was formed. The interval between the collecting electrodes was set at 10 mm. After formation of the collecting electrodes, an annealing treatment was carried out at 150° C. for an hour.

### Examples 2 to 8 and Comparative Examples 2 to 5

In formation of the first transparent electrode layer 61 in Example 1, deposition conditions (tin oxide content in target, substrate temperature, pressure, power density, carrier gas introduction amount and thickness) of the substrate-side ITO layer 61A and the surface-side ITO layer 61B were changed as shown in Table 1. A crystalline silicon-based solar cell schematically shown in FIG. 1 was prepared in the same manner as in Example 1 except for the aforementioned matters.

### Comparative Example 1

In formation of the first transparent electrode layer 61 in Example 1, the substrate-side ITO layer 61A was not formed, but only the ITO layer 61B was formed in a thickness of 90 nm. A crystalline silicon-based solar cell was prepared in the same manner as in Example 1 except for the aforementioned matters.

The deposition conditions and the evaluation results of film characteristics (carrier density and crystallinity) for the substrate-side ITO layer 61A and the surface-side ITO layer 61B in Examples and Comparative Examples are shown in Table 1. The film characteristics of the substrate-side ITO layer 61A and the surface-side ITO layer 61B, and the photoelectric conversion characteristic and presence/absence of warpage for the crystalline silicon-based solar cell are shown in Table 2.

TABLE 1

| | | Sn | power | substrate | Ar/O₂ | | carrier | | |
|---|---|---|---|---|---|---|---|---|---|
| | | content | density | temperature | flow | pressure | density | thickness | |
| | | (wt %) | (W/cm²) | (° C.) | ratio | (Pa) | (×10²⁰ cm⁻³) | (nm) | crystallinity |
| Example 1 | A | 5 | 0.5 | 150 | 50/0 | 0.2 | 5.8 | 10 | amorphous |
| | B | 5 | 0.5 | 150 | 50/1 | 0.2 | 1.5 | 80 | amorphous |
| Example 2 | A | 5 | 0.5 | 150 | 70/0 | 0.2 | 7.1 | 10 | amorphous |
| | B | 5 | 0.5 | 150 | 50/0.5 | 0.2 | 2.4 | 80 | amorphous |
| Example 3 | A | 10 | 0.5 | 150 | 50/0.2 | 0.2 | 10.2 | 10 | amorphous |
| | B | 10 | 0.5 | 150 | 50/0.8 | 0.2 | 2.4 | 80 | amorphous |
| Example 4 | A | 5 | 0.5 | 150 | 50/0 | 0.2 | 5.8 | 10 | amorphous |
| | B | 5 | 0.5 | 150 | 50/0.5 | 0.2 | 2.4 | 80 | amorphous |
| Example 5 | A | 5 | 0.5 | 150 | 50/0 | 0.2 | 5.8 | 10 | amorphous |
| | B | 5 | 0.5 | 150 | 50/0.4 | 0.2 | 3.0 | 80 | amorphous |
| Example 6 | A | 5 | 1 | 150 | 70/0 | 0.2 | 7.4 | 10 | crystalline |
| | B | 5 | 0.5 | 150 | 50/0.5 | 0.2 | 2.4 | 80 | amorphous |
| Example 7 | A | 5 | 0.5 | 150 | 70/0 | 0.2 | 7.1 | 45 | amorphous |
| | B | 5 | 0.5 | 150 | 50/0.5 | 0.2 | 2.4 | 45 | amorphous |
| Example 8 | A | 5 | 0.5 | 150 | 70/0 | 0.2 | 7.1 | 60 | amorphous |
| | B | 5 | 0.5 | 150 | 50/0.5 | 0.2 | 2.4 | 30 | amorphous |
| Comparative | B | 5 | 0.5 | 150 | 50/1 | 0.2 | 1.5 | 90 | amorphous |
| Example 1 | | | | | | | | | |
| Comparative | A | 5 | 0.5 | 150 | 50/1 | 0.2 | 1.5 | 10 | amorphous |
| Example 2 | B | 5 | 0.5 | 150 | 50/0 | 0.2 | 5.8 | 80 | amorphous |
| Comparative | A | 5 | 1 | 150 | 70/0 | 0.2 | 7.4 | 10 | crystalline |
| Example 3 | B | 5 | 1 | 150 | 50/0 | 0.2 | 5.1 | 80 | crystalline |
| Comparative | A | 5 | 0.5 | 150 | 70/0 | 0.2 | 7.1 | 10 | amorphous |
| Example 4 | B | 5 | 1 | 150 | 50/0 | 0.2 | 5.1 | 80 | crystalline |
| Comparative | A | 5 | 0.5 | 150 | 50/0 | 0.2 | 5.8 | 10 | amorphous |
| Example 5 | B | 5 | 0.5 | 150 | 100/0 | 0.2 | 8.5 | 80 | amorphous |

TABLE 2

| | ITO film | | | | | | | | | | |
|---|---|---|---|---|---|---|---|---|---|---|---|
| | carrier | | thick- | | | | photoelectric conversion | | | | |
| | density | | ness | | | | properties | | | | |
| | (×10²⁰ cm⁻³) | | (nm) | | crystallinity | | Jsc | Voc | F.F. | Eff. | |
| | A | B | A | B | A | B | (mA · cm⁻²) | (mV) | (%) | (%) | warpage |
| Example 1 | 5.8 | 1.5 | 10 | 80 | amorphous | amorphous | 37.05 | 0.701 | 74.22 | 19.28 | no |
| Example 2 | 7.1 | 2.4 | 10 | 80 | amorphous | amorphous | 37.05 | 0.711 | 73.00 | 19.23 | no |
| Example 3 | 10.2 | 2.4 | 10 | 80 | amorphous | amorphous | 37.01 | 0.711 | 76.40 | 20.10 | no |
| Example 4 | 5.8 | 2.4 | 10 | 80 | amorphous | amorphous | 36.85 | 0.719 | 74.33 | 19.69 | no |
| Example 5 | 5.8 | 3.0 | 10 | 80 | amorphous | amorphous | 36.77 | 0.709 | 74.28 | 19.36 | no |
| Example 6 | 7.4 | 2.4 | 10 | 80 | crystalline | amorphous | 36.85 | 0.655 | 72.30 | 17.45 | yes |
| Example 7 | 7.1 | 2.4 | 45 | 45 | amorphous | amorphous | 36.13 | 0.688 | 71.80 | 17.85 | no |
| Example 8 | 7.1 | 2.4 | 60 | 30 | amorphous | amorphous | 35.88 | 0.686 | 71.90 | 17.70 | no |
| Comparative | — | 1.5 | — | 90 | — | amorphous | 36.01 | 0.668 | 72.30 | 17.39 | no |
| Example 1 | | | | | | | | | | | |
| Comparative | 1.5 | 5.8 | 10 | 80 | amorphous | amorphous | 36.63 | 0.655 | 71.21 | 17.09 | no |
| Example 2 | | | | | | | | | | | |
| Comparative | 7.4 | 5.1 | 10 | 80 | crystalline | crystalline | 35.95 | 0.633 | 72.30 | 16.45 | yes |
| Example 3 | | | | | | | | | | | |
| Comparative | 7.1 | 5.1 | 10 | 80 | amorphous | crystalline | 35.96 | 0.642 | 72.10 | 16.65 | yes |
| Example 4 | | | | | | | | | | | |
| Comparative | 5.8 | 8.5 | 10 | 80 | amorphous | amorphous | 36.22 | 0.670 | 70.50 | 17.11 | no |
| Example 5 | | | | | | | | | | | |

From the results of the Examples and Comparative Examples described above, it is apparent that by providing a transparent electrode layer having a high carrier density at the junction interface between a silicon-based thin-film and a transparent electrode layer, a solar cell having a high short circuit current, open circuit voltage and fill factor can be prepared. Improvement of the fill factor is considered to result from improvement of electrical junction between the silicon-based thin-film and the transparent electrode layer. Improvement of the open circuit voltage is considered to result from suppression of carrier recombination by control of band bending. Improvement of the short circuit current is considered to result from the transparency (low carrier density) of the surface-side electroconductive layer.

From comparison of Example 1 and Comparative Examples 1 and 2, it is apparent that by providing a layer having a relatively high carrier density as the substrate-side electroconductive layer A in contact with the conductive silicon-based thin-film, the open circuit voltage Voc and the fill factor F.F. are particularly improved. This is considered to be because by improving junction at the interface between the conductive silicon-based thin-film and the transparent electrode, the fill factor is improved, and band bending of the conductive silicon-based thin-film is adjusted, whereby reduction of the open circuit voltage by carrier recombination is suppressed.

By comparison of Examples 2, 7 and 8 in which the thickness of each of the substrate-side electroconductive layer and the surface-side electroconductive layer is changed, it is apparent that the short circuit current density increases as the thickness of the substrate-side electroconductive layer A having a relatively high carrier density is decreased. From comparison of Examples 1, 4 and 5 and Comparative Example 5, it is apparent that by decreasing the carrier density of the surface-side electroconductive layer B, the short circuit current density may be increased. From these results, it is apparent that by providing the substrate-side electroconductive layer A having a relatively high carrier density, the short circuit current density may be increased. This is considered to result from suppression of a loss of light absorption by the transparent electrode layer due to improvement of junction between the silicon-based thin-film and the transparent electrode and decreasing of the average carrier density of the overall transparent electrode.

From comparison of Example 2 and Example 6 and comparison of Comparative Example 3 and Comparative Example 4, it is apparent that by forming an amorphous film, warpage of the cell may be suppressed, leading to an increase in open circuit voltage, if the carrier densities of transparent electroconductive layers are comparable.

### DESCRIPTION OF REFERENCE SIGNS

1 conductive single-crystal silicon substrate
21, 22 intrinsic silicon-based thin-film
41, 42 conductive silicon-based thin-film
61, 62 transparent electrode layer
61A substrate-side electroconductive layer
61B surface-side electroconductive layer
71, 71 collecting electrode

1. A crystalline silicon-based solar cell comprising a silicon-based thin-film of a first conductivity type and a first transparent electrode layer, in this order, on one surface of a conductive single-crystal silicon substrate of the first conductivity type or an opposite conductivity type; and a silicon-based thin-film of the opposite conductivity type and a second transparent electrode layer, in this order, on the other surface of the conductive single-crystal silicon substrate, wherein
the first transparent electrode layer and the second transparent electrode layer are each formed of a transparent conductive metal oxide, and
the first transparent electrode layer satisfies requirements (i) to (iii):
(i) at least two layers, including a substrate-side electroconductive layer and a surface-side electroconductive layer, are provided in the first transparent electrode layer, and the substrate-side electroconductive layer and the surface-side electroconductive layer are amorphous layers;
(ii) a total thickness of the first transparent electrode layer is 50 to 120 nm; and
(iii) a carrier density of the substrate-side electroconductive layer is higher than the carrier density of the surface-side electroconductive layer, and the carrier density of the surface-side electroconductive layer is 1 to 4×10²⁰ cm⁻³.

2. The crystalline silicon-based solar cell according to claim 1, wherein the crystalline silicon-based solar cell comprises a first intrinsic silicon-based thin-film between the conductive single-crystal silicon substrate and the silicon-based thin-film of the first conductivity type; and a second intrinsic silicon-based thin-film between the conductive single-crystal silicon substrate and the silicon-based thin-film of the opposite conductivity type.

3. The crystalline silicon-based solar cell according to claim 1, wherein a thickness d_{A} of the substrate-side electroconductive layer is 5 nm to 40 nm.

4. The crystalline silicon-based solar cell according to claim 1, wherein a thickness d_{A} of the substrate-side electroconductive layer and a thickness d_{B} of the surface-side electroconductive layer satisfy 0.5≦d_{B}/(d_{A}+d_{B})≦0.95.

5. (canceled)

6. (canceled)

7. The crystalline silicon-based solar cell according to claim 1, wherein a thickness of the conductive single-crystal silicon substrate is 250 μm or less.

8. The crystalline silicon-based solar cell according to claim 1, wherein the crystalline silicon-based solar cell further comprises a collecting electrode on each of the first transparent electrode layer and the second transparent electrode layer.
